(19) United States
(12) Patent Application Publication
(10) Pub. No.: US 2025/0038112 A1
(43) Pub. Date: Jan. 30, 2025

(54) SEMICONDUCTOR PACKAGE INCLUDING A PLURALITY OF SEMICONDUCTOR CHIPS

(71) Applicant: SAMSUNG ELECTRONICS CO., LTD., Suwon-si (KR)

(72) Inventor: Taejoo HWANG, Suwon-si (KR)

(21) Appl. No.: 18/437,236

(22) Filed: Feb. 8, 2024

(30) Foreign Application Priority Data
Jul. 27, 2023 (KR) 10-2023-0098358

(51) Int. Cl. H01L 23/538; H01L 23/00; H01L 23/31; H01L 23/48; H01L 23/498; H01L 25/065

(52) U.S. Cl. CPC H01L 23/5381; H01L 23/3128; H01L 23/481; H01L 23/49822; H01L 24/16; H01L 24/32; H01L 24/73; H01L 25/0652; H01L 2224/16225; H01L 2224/32225; H01L 2224/73204; H01L 2924/181

(57) ABSTRACT

A semiconductor package includes a first substrate. A first lower semiconductor chip is disposed on the first substrate. A bridge structure is laterally spaced apart from the first lower semiconductor chip, on the first substrate. A second substrate is disposed on the first lower semiconductor chip and the bridge structure. A first upper semiconductor chip is disposed on the second substrate. The first upper semiconductor chip is spaced apart from the first lower semiconductor chip in a plan view. The bridge structure includes a base structure. Conductive vias are disposed in the base structure and are in contact with the first substrate. The first upper semiconductor chip is electrically connected to the first lower semiconductor chip through the conductive vias.

### CROSS-REFERENCE TO RELATED APPLICATION

This application is based on and claims priority under 35 U.S.C. § 119 to Korean Patent Application No. 10-2023-0098358, filed on Jul. 27, 2023 in the Korean Intellectual Property office, the disclosure of which is incorporated by reference herein in its entirety.

### TECHNICAL FIELD

The inventive concept relates to a semiconductor package, and more particularly, to a semiconductor package including a plurality of semiconductor chips.

### DISCUSSION OF THE RELATED ART

Semiconductor packages are structures that house an integrated circuit (IC) chip to protect the chip from damage and to facilitate a connection between the chip and the electronic products that they are incorporated into. In general, in a semiconductor package, semiconductor chips are mounted on a printed circuit board and electrically connected to the printed circuit board by using bonding wires or bumps. With the development of the electronics industry, various studies are being conducted to increase the reliability, integration, and miniaturization of semiconductor packages.

### SUMMARY

A semiconductor package includes a first substrate. A first lower semiconductor chip is disposed on the first substrate. A bridge structure is laterally spaced apart from the first lower semiconductor chip, on the first substrate. A second substrate is disposed on the first lower semiconductor chip and the bridge structure. A first upper semiconductor chip is disposed on the second substrate. The first upper semiconductor chip is spaced apart from the first lower semiconductor chip in a plan view. The bridge structure includes a base structure, and conductive vias disposed in the base structure and in contact with the first substrate. The first upper semiconductor chip is electrically connected to the first lower semiconductor chip through the conductive vias.

A semiconductor package includes a first substrate. A first lower chiplet is disposed on the first substrate. A second lower chiplet is laterally spaced apart from the first lower chiplet, on the first substrate. A bridge structure is disposed between the first lower chiplet and the second lower chiplet, on the first substrate. A second substrate is disposed on the second lower chiplet and the bridge structure. A first upper chiplet is disposed on the second substrate. The first upper chiplet is electrically connected to the first lower chiplet through the second substrate and the bridge structure.

A semiconductor package includes a first insulating layer, a first seed pattern, and a first redistribution substrate including a first conductive pattern disposed on the first seed pattern. The first insulating layer includes a photo sensitive polymer. A first lower semiconductor chip is disposed on an upper surface of the first redistribution substrate. Second lower semiconductor chips are laterally spaced apart from the first lower semiconductor chip, on the upper surface of the first redistribution substrate. Bridge structures are respectively disposed between the first lower semiconductor chip and the second lower semiconductor chips, on the upper surface of the first redistribution substrate. Conductive structures are laterally spaced apart from the second lower semiconductor chips, on the upper surface of the first redistribution substrate. A first molding layer covers the first lower semiconductor chip, the second lower semiconductor chips, and the bridge structures, on the upper surface of the first redistribution substrate. A second redistribution substrate is disposed on the first molding layer and the conductive structures. First upper semiconductor chips are disposed on the second redistribution substrate. A second molding layer is disposed on an upper surface of the second redistribution substrate, and covers the first upper semiconductor chips. The second redistribution substrate includes a second insulating layer, a second seed pattern, and a second conductive pattern disposed on the second seed pattern. The second insulating layer includes a photo sensitive polymer. The first upper semiconductor chips are apart from the first lower semiconductor chip in a plan view. Each of the bridge structures includes a base structure, and conductive vias disposed in the base structure and in contact with the first redistribution substrate. The first upper semiconductor chips are electrically connected to the first lower semiconductor chip through the second redistribution substrate and the conductive vias.

### BRIEF DESCRIPTION OF THE DRAWINGS

Embodiments will be more clearly understood from the following detailed description taken in conjunction with the accompanying drawings in which:

FIG. 1A is a plan view of a semiconductor package according to an embodiment of the present disclosure;

FIG. 1B is a cross-sectional view of a semiconductor package taken along line I-II in FIG. 1A;

FIG. 1C is a diagram illustrating a first lower semiconductor chip, second lower semiconductor chips, and transmission of electrical signals between first upper semiconductor chips, according to an embodiment of the present disclosure;

FIG. 2 is a cross-sectional view of a semiconductor package according to an embodiment of the present disclosure;

FIG. 3A is a plan view of a semiconductor package according to an embodiment of the present disclosure;

FIG. 3B is a cross-sectional view of a semiconductor package taken along line I-II in FIG. 3A;

FIG. 4 is a cross-sectional view of a semiconductor package according to an embodiment of the present disclosure; and

FIG. 5 is a cross-sectional view of a semiconductor package according to an embodiment of the present disclosure.

### DETAILED DESCRIPTION OF THE EMBODIMENTS

In the inventive concept, the same reference numerals may refer to as the same components throughout the specification and the drawings. A semiconductor package, according to embodiments of the inventive concept, are described herein.

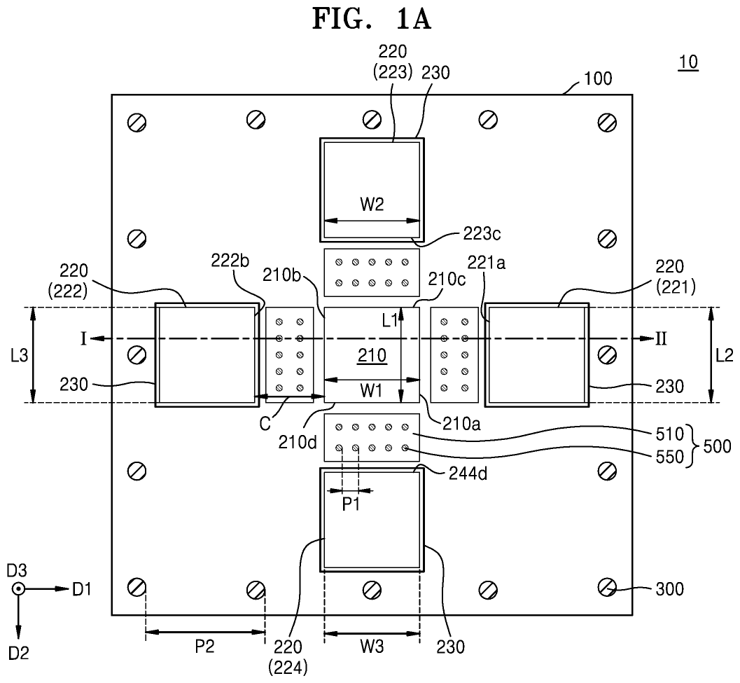

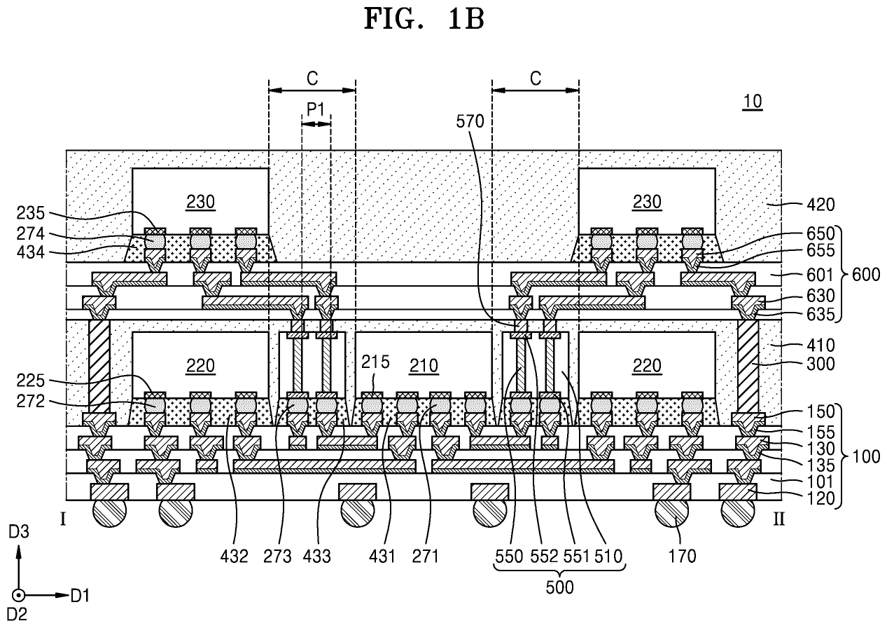

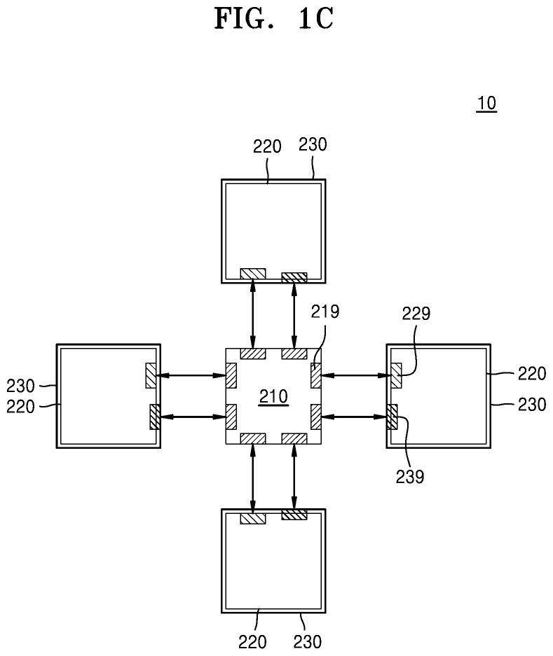

FIG. 1A is a plan view of a semiconductor package 10 according to an embodiment of the present disclosure. FIG. 1B is a cross-sectional view of the semiconductor package 10 taken along line I-II in FIG. 1A.

Referring to FIGS. 1A and 1B, the semiconductor package 10 may include a first substrate 100, solder ball terminals 170, a first lower semiconductor chip 210, second lower semiconductor chips 220, a bridge structure 500, conductive posts 300, a first molding layer 410, a second substrate 600, a second molding layer 420, and first upper semiconductor chips 230.

The first substrate 100 may include a high-density wiring substrate. For example, the first substrate 100 may include first wirings, and the first wirings may be disposed in the first substrate 100 at a high density. The first wirings may have relatively small widths and small pitches. For example, the first substrate 100 may include a redistribution substrate. As an example, the first substrate 100 may include a printed circuit board, such as a multi-layer board (MLB) and/or a high-density interconnection (HDI) substrate. In FIGS. 1B, 2, 3B, 4, and 5, for convenience, the first substrate 100 is illustrated for the case of a redistribution substrate, but the embodiments are not necessarily limited thereto. Types and components of the first substrate 100 may be variously modified.

For example, when the first substrate 100 includes a redistribution substrate, the first substrate 100 may, as illustrated in FIG. 1B, include a first insulating layer 101, under bump patterns 120, first redistribution patterns 130, first seed patterns 135, first seed pads 155, and first redistribution pads 150. The first insulating layer 101 may include an organic material such as a photo imageable dielectric (PID) material. The PID material may include polymer. The PID material may include, for example, photosensitive polyimide, polybenzoxazole, phenol-based polymer, and/or benzocyclobutene-based polymer. The first insulating layer 101 may be provided in plural. The number of stacked first insulating layers 101 may be variously modified. For example, a plurality of first insulating layers 101 may include the same material. Interfaces between the adjacent first insulating layers 101 might not be observable.

A first direction D1 may be parallel with a bottom surface of the lowermost first insulating layer 101, among the first insulating layers 101. A second direction D2 may be parallel with the bottom surface of the lowermost first insulating layer 101, and may be substantially perpendicular to the first direction D1. A third direction D3 may be substantially perpendicular to the first direction D1 and the second direction D2.

The under bump patterns 120 may be disposed in the lowermost first insulating layer 101. A bottom surface of the under bump patterns 120 might not be covered by the lowermost first insulating layer 101. The under bump patterns 120 may function as pads of solder ball terminals 170. The under bump patterns 120 may be laterally spaced apart from each other, and electrically disconnected from each other (e.g., electrically insulated from each other). That certain two components are laterally spaced apart from each other may mean that they are horizontally spaced apart from each other. “Horizontal” may mean parallel with a bottom surface of the first substrate 100 or the first direction D1. The lower surface of the first substrate 100 may include a bottom surface of the lowermost first insulating layer 101 and bottom surfaces of the under bump patterns 120. The under bump patterns 120 may include a metal such as copper.

The first redistribution patterns 130 may be disposed on the under bump patterns 120, and may be electrically connected to the under bump patterns 120. The first redistribution patterns 130 may include a metal such as copper. Being electrically connected to the first substrate 100 may mean being electrically connected to any one of the first redistribution patterns 130. That two components are electrically connected to each other may include a direct connection between them or an indirect connection with another component disposed therebetween that completes the electrical connection.

Each of the first redistribution patterns 130 may include a first via portion and a first wiring portion. The first via portion may be disposed in the corresponding first insulating layer 101. The first wiring portion may be disposed on the first via portion, and may be connected to the first via portion without a boundary surface. A width of the first wiring portion may be greater than a width of the first via portion. The first wiring portion may extend onto an upper surface of the first insulating layer 101 corresponding thereto. In the inventive concept, a via may include a component for vertical connection, and a wiring may include a component for horizontal connection. “Vertical” may mean “being parallel with the third direction D3”.

The first redistribution patterns 130 may include first lower redistribution patterns and first upper redistribution patterns, which are stacked. The first lower redistribution pattern may be disposed on the under bump pattern 120 corresponding thereto. The first upper redistribution pattern may be disposed on the first lower redistribution pattern, and in contact with the first lower redistribution pattern.

The first seed patterns 135 may be respectively disposed on lower surfaces of the first redistribution patterns 130. For example, each of the first seed patterns 135 may cover a lower surface and sidewalls of the first via portion of the first redistribution pattern 130 and a lower surface of the first wiring portion, which correspond to each of the first seed patterns 135. The first seed patterns 135 may include a material that is different from materials of the under bump patterns 120 and the first redistribution patterns 130. For example, the first seed patterns 135 may include a conductive seed material. The conductive seed material may include copper, titanium, and/or an alloy thereof. The first seed patterns 135 may function as barrier layers to prevent diffusion of a material included in the first redistribution patterns 130.

The first redistribution pads 150 may be disposed in the uppermost first insulating layer 101, and may extend onto the upper surface of the uppermost first insulating layer 101. A lower portion of each of the first redistribution pads 150 may be disposed in the uppermost first insulating layer 101. An upper portion of each of the first redistribution pads 150 may be disposed on an upper surface of the uppermost first insulating layer 101. The upper portion of each of the first redistribution pads 150 may have a greater width than the lower portion thereof, and may be connected to the lower portion thereof. The first redistribution pads 150 may be laterally spaced apart from each other. The first redistribution pads 150 may be disposed on the first redistribution patterns 130, and may be connected to the first redistribution patterns 130. At least one of the first redistribution pads 150 may be connected to the under bump pattern 120 corresponding thereto via the first upper redistribution pattern and the first lower redistribution pattern. Because the first redistribution patterns 130 are provided, any one first redistribution pad 150 might not be vertically aligned with the under bump pattern 120 electrically connected to the first redistribution pad 150. Accordingly, an arrangement of the first redistribution pads 150 may be freely designed. The number of first redistribution patterns 130 stacked between the under bump patterns 120 and the first redistribution pads 150 is not necessarily limited to the illustrated arrangement, but may be variously modified.

The first seed pads 155 may be respectively disposed on the lower surfaces of the first redistribution pads 150. The first seed pads 155 may be disposed between the first upper redistribution patterns among the first redistribution patterns 130 and the first redistribution pads 150, and may extend between the uppermost first insulating layer 101 and the first redistribution pads 150. The first seed pads 155 may include a different material from the first redistribution pads 150. The first seed pads 155 may include, for example, a conductive seed material.

The solder ball terminals 170 may be disposed under a lower surface of the first substrate 100. For example, the solder ball terminals 170 may be respectively arranged under lower surfaces of the under bump patterns 120, and may be electrically connected to the under bump patterns 120. The solder ball terminals 170 may be electrically connected to the first redistribution patterns 130 via the under bump patterns 120. The solder ball terminals 170 may be electrically separated from each other. The solder ball terminals 170 may include a solder material. The solder material may include, for example, tin, bismuth, lead, silver, or an alloy thereof. The solder material might not include copper, but is not necessarily limited thereto. The solder ball terminals 170 may include signal solder ball terminals, ground solder ball terminals, and power solder ball terminals.

The first lower semiconductor chip 210 may be mounted on an upper surface of the first substrate 100. For example, the first lower semiconductor chip 210 may be disposed on a center region of the first substrate 100, in a plan view.

The first lower semiconductor chip 210 may include first chip pads 215, a first semiconductor die, a first integrated circuit layer. A lower surface of the first semiconductor die may face the first substrate 100, and may include an active surface. The first integrated circuit layer may include first insulating layers, first conductive wirings, and first integrated circuits. The first integrated circuits may include logic circuits, and may be disposed under a lower surface of the first semiconductor die. Alternatively, the first integrated circuits may include memory circuits. The first insulating layers may be stacked under the lower surfaces of the first semiconductor die. Any one of the first insulating layers may cover the first integrated circuits. The first conductive wirings may be disposed between the first insulating layers and may be electrically connected to the first integrated circuits. The first chip pads 215 may be disposed on the lower surface of the first lower semiconductor chip 210. The lower surface of the first lower semiconductor chip 210 may include the lower surface of the first integrated circuit layer. The first chip pads 215 may be electrically connected to the first integrated circuits via the first conductive wirings. The first chip pads 215 may include a metal such as aluminum. That a component is electrically connected to a semiconductor chip may mean that the component is electrically connected to integrated circuits via chip pads of the semiconductor chip.

The semiconductor package 10 may further include first lower bumps 271. The first lower bumps 271 may be disposed between the first substrate 100 and the first lower semiconductor chip 210. For example, the first lower bumps 271 may be disposed between the first redistribution pads 150 and the first chip pads 215 corresponding to the first lower bumps 271, and may be connected to the first redistribution pads 150 and the first chip pads 215. Accordingly, the first lower semiconductor chip 210 may be electrically connected to the first substrate 100 via the first lower bumps 271. The first lower semiconductor chip 210 may be electrically connected to the solder ball terminals 170 via the first substrate 100. The first lower bumps 271 may include solder balls, and the solder balls may include a solder material. The first lower bumps 271 may further include filler patterns. The filler patterns may include a metal that is different from the solder material. The filler patterns may include, for example, copper.

The semiconductor package 10 may further include a first underfill layer 431. The first underfill layer 431 may be disposed in a first gap region between the first substrate 100 and the first lower semiconductor chip 210 and may cover sidewalls of the first lower bumps 271. The first underfill layer 431 may include insulating polymer such as epoxy polymer.

The second lower semiconductor chips 220 may be disposed on the upper surface of the first substrate 100. The second lower semiconductor chips 220 may perform different functions from the first lower semiconductor chip 210, but are not necessarily limited thereto. The second lower semiconductor chips 220 may transceive (e.g., transmit and/or receive) electrical signals with the first lower semiconductor chip 210 via the first substrate 100.

The second lower semiconductor chips 220 may include edge semiconductor chips. For example, the second lower semiconductor chips 220 may be disposed on an edge region of the first substrate 100, in a plan view. The edge region of the first substrate 100 may be disposed between a center region and sidewalls of the first substrate 100, in a plan view. The edge region of the first substrate 100 may surround the center region of the first substrate 100, in a plan view.

As illustrated in FIG. 1B, each of the second lower semiconductor chips 220 may include second chip pads 225, a second semiconductor die, and a second integrated circuit layer. A lower surface of the second semiconductor die may face the first substrate 100. The second integrated circuit layer may include second insulating layers, second conductive wirings, and second integrated circuits. The second integrated circuits may include logic circuits, and may be disposed under the lower surface of the second semiconductor die. Alternatively, the second integrated circuits may include memory circuits. The second insulating layers may be stacked under the lower surfaces of the second semiconductor die. Any one of the second insulating layers may cover the second integrated circuits. The second conductive wirings may be disposed between the second insulating layers and may be electrically connected to the second integrated circuits. The second chip pads 225 may be disposed below a lower surface of the second lower semiconductor chip 220 corresponding thereto. The lower surface of the second lower semiconductor chip 220 may include the lower surface of the second integrated circuit layer. The second chip pads 225 may be electrically connected to the second integrated circuits via the second conductive wirings. The second chip pads 225 may include a metal such as aluminum.

Each of the second lower semiconductor chips 220 may be laterally spaced apart from the first lower semiconductor chip 210. The second lower semiconductor chips 220 may be disposed symmetrically with respect to the first lower semiconductor chip 210, in a plan view. For example, the first lower semiconductor chip 210 may be disposed between any two of the second lower semiconductor chips 220.

For example, the second lower semiconductor chips 220 may include, as illustrated in FIG. 1A, a first edge semiconductor chip 221, a second edge semiconductor chip 222, a third edge semiconductor chip 223, and a fourth edge semiconductor chip 224. The first edge semiconductor chip 221 may be laterally spaced apart from a first sidewall 210a of the first lower semiconductor chip 210. For example, one sidewall 221a of the first edge semiconductor chip 221 may face the first sidewall 210a of the first lower semiconductor chip 210, and may be spaced apart from the first sidewall 210a of the first lower semiconductor chip 210. The one sidewall 221a of the first edge semiconductor chip 221 may be spaced apart from the first sidewall 210a of the first lower semiconductor chip 210.

The second edge semiconductor chip 222 may be spaced apart from a second sidewall 210b of the first lower semiconductor chip 210 laterally. The second sidewall 210b of the first lower semiconductor chip 210 may face the first sidewall 210a of the first lower semiconductor chip 210. One sidewall 222b of the second edge semiconductor chip 222 may face the second sidewall 210b of the first lower semiconductor chip 210, and may be spaced apart from the second sidewall 210b of the first lower semiconductor chip 210. The one sidewall 222b of the second edge semiconductor chip 222 may be parallel with the second sidewall 210b of the first lower semiconductor chip 210.

The third edge semiconductor chip 223 may be laterally spaced apart from a third sidewall 210c of the first lower semiconductor chip 210. The third sidewall 210c of the first lower semiconductor chip 210 may be adjacent to the first sidewall 210a and the second sidewall 210b. For example, one sidewall 223c of the third edge semiconductor chip 223 may face the third sidewall 210c of the first lower semiconductor chip 210, and may be spaced apart from the third sidewall 210c of the first lower semiconductor chip 210. The one sidewall 223c of the third edge semiconductor chip 223 may be parallel with the third sidewall 210c of the first lower semiconductor chip 210.

The fourth edge semiconductor chip 224 may be laterally spaced apart from a fourth sidewall 210d of the first lower semiconductor chip 210. The fourth sidewall 210d of the first lower semiconductor chip 210 may face the third sidewall 210c. For example, one sidewall 224d of the fourth edge semiconductor chip 224 may face the fourth sidewall 210d of the first lower semiconductor chip 210, and may be spaced apart from the fourth sidewall 210d of the first lower semiconductor chip 210. The one sidewall 224d of the fourth edge semiconductor chip 224 may be parallel with the fourth sidewall 210d of the first lower semiconductor chip 210.

According to some embodiments of the present disclosure, as illustrated in FIG. 1A, a distance C between the first lower semiconductor chip 210 and the second lower semiconductor chips 220 may be about 50 μm to about 2 mm. For example, the first edge semiconductor chip 221 may be spaced apart from the first sidewall 210a of the first lower semiconductor chip 210 at the distance C of about 50 μm to about 2 mm. The second edge semiconductor chip 222 may be spaced apart from the second sidewall 210b of the first lower semiconductor chip 210 at the distance C of about 50 μm to about 2 mm. The third edge semiconductor chip 223 may be spaced apart from the third sidewall 210c of the first lower semiconductor chip 210 at the distance C of about 50 μm to about 2 mm. The fourth edge semiconductor chip 224 may be spaced apart from the fourth sidewall 210d of the first lower semiconductor chip 210 at the distance C of about 50 μm to about 2 mm. Because the distance C between the first lower semiconductor chip 210 and the second lower semiconductor chips 220 is about 2 mm or less, an interface between the first lower semiconductor chip 210 and the second lower semiconductor chips 220 may be made more reliable. For example, electrical signal transmission between the first lower semiconductor chip 210 and the second lower semiconductor chips 220 may be performed at a high speed. Accordingly, electrical signal transmission between the first lower semiconductor chip 210 and the second lower semiconductor chips 220 may have high bandwidth density, low signal latency characteristics, and increased power efficiency characteristics. Because the distance C between the first lower semiconductor chip 210 and the second lower semiconductor chips 220 is about 5 μm or more, the manufacturing process of the semiconductor package 10 may be more easily performed.

According to some embodiments of the present disclosure, a length L1 of the first lower semiconductor chip 210 and a length L2 of the one sidewall 221a of the first edge semiconductor chip 221 may be the same as each other, or have a difference within about 10 μm. Accordingly, the interface between the first lower semiconductor chip 210 and the first edge semiconductor chip 221 may be made more reliable. The length L1 of the first lower semiconductor chip 210 and a length L3 of the one sidewall 222b of the second edge semiconductor chip 222 may be the same as each other, or have a difference within about 10 μm. The interface between the first lower semiconductor chip 210 and the first edge semiconductor chip 221 may be more reliable. In this case, the length L1 of the first lower semiconductor chip 210 may be the same as the length of the first sidewall 210a of the first lower semiconductor chip 210 and the length of the second sidewall 210b of the first lower semiconductor chip 210. A length of a certain component may be measured in a direction parallel with the second direction D2. A width W1 of the first lower semiconductor chip 210 and a width W2 of the one sidewall 223c of the third edge semiconductor chip 223 may be the same as each other, or have a difference within about 10 μm. The width W1 of the first lower semiconductor chip 210 and a width W3 of the one sidewall 224d of the fourth edge semiconductor chip 224 may be the same as each other, or have a difference within about 10 μm. The width W1 of the first lower semiconductor chip 210 may be the same as a width of the third sidewall 210c of the first lower semiconductor chip 210 and a width of the fourth sidewall 210d. Accordingly, the interface between the first lower semiconductor chip 210 and the third edge semiconductor chip 223 and between the first lower semiconductor chip 210 and the fourth edge semiconductor chip 224 may be made more reliable. That widths, lengths, and levels of certain components are the same may mean the same error range that may occur in the process.

For example, the first lower semiconductor chip 210 may have a square shape in a plan view, and the length L1 of the first lower semiconductor chip 210 may be substantially the same as the width W1 of the first lower semiconductor chip 210. However, the inventive concept is not necessarily limited thereto. The second lower semiconductor chips 220 may have a square or rectangular planar shape.

The semiconductor package 10 may further include second lower bumps 272, as illustrated in FIG. 1B. The second lower bumps 272 may be disposed between the first substrate 100 and the second lower semiconductor chips 220. For example, the second lower bumps 272 may be disposed between the first redistribution pads 150 and the second chip pads 225, which correspond to the second lower bumps 272, and may be connected to the first redistribution pads 150 and the second chip pads 225. Accordingly, the second lower semiconductor chips 220 may be electrically connected to the first substrate 100 via the second lower bumps 272. The second lower semiconductor chips 220 may be electrically connected to the first lower semiconductor chip 210 and the solder ball terminals 170 via the first substrate 100. The second lower bumps 272 may include solder balls. The second lower bumps 272 may further include filler patterns.

The semiconductor package 10 may further include second underfill layers 432. The second underfill layer 432 may be disposed in a second gap region between the first substrate 100 and the second lower semiconductor chip 220 and may cover sidewalls of the second lower bumps 272. The second underfill layers 432 may include insulating polymer such as epoxy polymer.

The bridge structure 500 may be disposed on the first substrate 100. The bridge structure 500 may be laterally spaced apart from the first lower semiconductor chip 210 and the second lower semiconductor chips 220. The bridge structure 500 may be provided in plural. The plurality of bridge structures 500 may be respectively disposed between the first lower semiconductor chip 210 and the second lower semiconductor chips 220. For example, as illustrated in FIG. 1A, each of the plurality of bridge structures 500 may be disposed between the first lower semiconductor chip 210 and the first edge semiconductor chip 221, between the first lower semiconductor chip 210 and the second edge semiconductor chip 222, between the first lower semiconductor chip 210 and the third edge semiconductor chip 223, and between the first lower semiconductor chip 210 and the fourth edge semiconductor chip 224. As an example, the number of bridge structures 500 may be the same as the number of second lower semiconductor chips 220. The planar shape, size, and planar area of each of the plurality of bridge structures 500 may be variously modified without necessarily being limited to what is shown the illustration of FIG. 1A. The number of bridge structures 500 may be variously modified without necessarily being limited to what is shown in the illustration of FIG. 1A.

Each of the plurality of bridge structures 500 may include a base structure 510 and conductive vias 550, as illustrated in FIG. 1B. The base structure 510 may include a semiconductor substrate. The semiconductor substrate may include silicon, germanium, or a combination thereof. As an example, the base structure 510 may include an insulating material. The conductive vias 550 may be disposed in the base structure 510. The conductive vias 550 may penetrate the base structure 510. The conductive vias 550 may be electrically connected to the first lower semiconductor chip 210 via the first substrate 100. Being electrically connected to the plurality of bridge structures 500 may mean being electrically connected to at least one of the conductive vias 550 included in the corresponding bridge structure 500. The conductive vias 550 may include a metal, such as copper, tungsten, titanium, and an alloy thereof. The conductive vias 550 may have a first pitch P1. The first pitch P1 may be about 0.4 μm to about 5 μm. Because the first pitch P1 is about 0.4 μm or more, a manufacturing process of the conductive vias 550 may be relatively simple.

The plurality of bridge structures 500 may further include first conductive pads 551 and/or second conductive pads 552. The first conductive pads 551 may be disposed under a lower surface of the base structure 510, and may be in contact with the conductive vias 550. The second conductive pads 552 may be disposed on an upper surface of the base structure 510, and may be in contact with the conductive vias 550. The second conductive pads 552 may be electrically connected to a first conductive pads 551 via the conductive vias 550. The first conductive pads 551 and the second conductive pads 552 may include a metal, such as copper, titanium, and an alloy thereof. The plurality of bridge structures 500 might not include integrated circuits, but are not necessarily limited thereto. As an example, the plurality of bridge structures 500 may further include a passive device or a switching device.

The semiconductor package 10 may further include third lower bumps 273. The third lower bumps 273 may be disposed between the first substrate 100 and the plurality of bridge structures 500. For example, the third lower bumps 273 may be disposed between the first redistribution pads 150 and the first conductive pads 551, which correspond to the third lower bumps 273, and may be in contact with the first redistribution pads 150 and the first conductive pads 551. Accordingly, the plurality of bridge structures 500 may be electrically connected to the first substrate 100 via the third lower bumps 273. The first conductive pads 551 may be omitted, and the third lower bumps 273 may be directly connected to the lower surfaces of the conductive vias 550. Each of the third lower bumps 273 may include silver and/or filler patterns.

The semiconductor package 10 may further include a third underfill layer 433. The third underfill layer 433 may be disposed in a third gap region between the first substrate 100 and the plurality of bridge structures 500, and may cover sidewalls of the third lower bumps 273. The third underfill layer 433 may include insulating polymer such as epoxy polymer.

The conductive posts 300 may be disposed on an upper surface of the edge region of the first substrate 100. The conductive posts 300 may be disposed between the second lower semiconductor chips 220 and the sidewalls of the first substrate 100, in a plan view. The conductive posts 300 may be laterally spaced apart from the second lower semiconductor chips 220 and the first lower semiconductor chip 210. For example, the conductive posts 300 may have a cylindrical shape. The conductive posts 300 may have a second pitch (P2 in FIG. 1A). The second pitch P2 may be greater than the first pitch P1. The second pitch P2 may be about 40 μm or more. For example, the second pitch P2 may be about 40 μm to about 1 m. Because the second pitch P2 is about 40 μm or more, the aspect ratio of the conductive posts 300 might not be excessively large. Accordingly, the conductive posts 300 may have structural stability, and the manufacturing process of the conductive posts 300 may be more easily performed. The conductive posts 300 may be respectively disposed on the corresponding first redistribution pads 150, and may be connected to the first redistribution pads 150. Accordingly, the conductive posts 300 may be electrically connected to the solder ball terminals 170 via the first substrate 100. For example, the conductive posts 300 may be electrically connected to the power solder ball terminal or the ground solder ball terminal among the solder ball terminals 170. The conductive posts 300 may include, for example, a metal, such as copper and/or tungsten. The conductive posts 300 may include conductive structures.

The first molding layer 410 may be disposed on the upper surface of the first substrate 100 and may cover the first lower semiconductor chip 210, the second lower semiconductor chips 220, and the plurality of bridge structures 500. For example, the first molding layer 410 may cover the base structure 510, and may be spaced apart from the conductive vias 550. The first molding layer 410 may cover sidewalls of the conductive posts 300, and might not extend onto upper surfaces of the conductive posts 300. For example, an upper surface of the first molding layer 410 may be coplanar with the upper surfaces of the conductive posts 300. The first molding layer 410 may include insulating polymer such as epoxy-based molding compound. The first molding layer 410 may include a different material from the first through third underfill layers 431 through 433. At least one of the first through third underfill layers 431 through 433 may be omitted, and the first molding layer 410 may further extend into a corresponding region among a first gap region, second gap regions, and a third gap region.

The second substrate 600 may be disposed on the second molding layer 420 and the conductive posts 300. The second substrate 600 may be disposed on the first lower semiconductor chip 210, the second lower semiconductor chips 220, and the bridge structure 500. The second substrate 600 may be electrically connected to the conductive posts 300.

The second substrate 600 may include a high-density wiring substrate. For example, the second substrate 600 may include second wirings, and the second wirings may be disposed in the second substrate 600 at a high density. The second wirings may have relatively small widths and small pitches. For example, the second substrate 600 may include a redistribution substrate. As an example, the second substrate 600 may include a printed circuit board, such as an MLB and/or an HDI substrate. In FIGS. 1B, 2, 3B, 4, and 5, for convenience, the second substrate 600 is illustrated for the case of a redistribution substrate, but the embodiments are not necessarily limited thereto. Types and components of the second substrate 600 may be variously modified.

According to some embodiments of the present disclosure, when the second substrate 600 includes a redistribution substrate, the second substrate 600 may include a second insulating layer 601, second redistribution patterns 630, second seed patterns 635, second seed pads 655, and second redistribution pads 650. The second insulating layer 601 may include a plurality of second insulating layers 601. The plurality of second insulating layers 601 may be stacked on the first molding layer 410. The plurality of second insulating layers 601 may include a PID material. For example, the plurality of second insulating layers 601 may include the same material. Interfaces between the adjacent plurality of second insulating layers 601 might not be observable. The number of second insulating layers 601 may be variously modified.

The second redistribution patterns 630 may be disposed in and on the plurality of second insulating layers 601. Each of the second redistribution patterns 630 may include a second via portion and a second wiring portion. The second via portion may be disposed in the corresponding second insulating layer 601. The second wiring portion may be disposed on the second via portion, and may be connected to the second via portion without a boundary surface. A width of the second wiring portion of each of the second redistribution patterns 630 may be greater than a width of an upper surface of the second via portion. The second wiring portion of each of the second redistribution patterns 630 may extend onto the upper surface of the second insulating layer 601. The second redistribution patterns 630 may include a metal such as copper.

The second redistribution patterns 630 may include a second lower redistribution pattern and second upper redistribution patterns, which are stacked. The second lower redistribution pattern may be disposed on the corresponding conductive post 300, and may be in contact with the corresponding conductive post 300. The second upper redistribution pattern may be disposed on the second lower redistribution pattern, and may be in contact with the second lower redistribution pattern.

The second seed patterns 635 may be respectively disposed on lower surfaces of the second redistribution patterns 630. For example, each second seed pattern 635 may be disposed on the lower surface and sidewalls of the second via portion of the second redistribution pattern 630 corresponding to each second seed pattern 635, and may extend onto the line of the second wiring portion. The second seed patterns 635 may include a different material from the conductive posts 300 and the second redistribution patterns 630. For example, the second seed patterns 635 may include a conductive seed material. The second seed patterns 635 may function as barrier layers to prevent diffusion of materials included in the second redistribution patterns 630.

Each second redistribution pad 650 may be disposed on the corresponding second redistribution pattern 630, and may be in contact with the corresponding second redistribution pattern 630. For example, each second redistribution pad 650 may be disposed on the second lower redistribution pattern. The second redistribution pads 650 may be laterally spaced apart from each other. Lower portions of the second redistribution pads 650 may be disposed in the uppermost second insulating layer 601. Upper portions of the second redistribution pads 650 may extend onto the upper surface of the uppermost second insulating layer 601. The second redistribution pads 650 may include a metal such as copper.

The second redistribution pads 650 may be in contact with the conductive posts 300 via the second redistribution patterns 630. Because the second redistribution patterns 630 are provided, at least one second redistribution pad 650 might not be vertically aligned with the conductive post 300 electrically connected to the at least one second redistribution pad 650. Accordingly, an arrangement of the second redistribution pads 650 may be freely designed. The number of second redistribution patterns 630 stacked between the conductive posts 300 and the second redistribution pads is not necessarily limited to the illustrated arrangement, but may be variously modified. For example, one second redistribution pattern 630 or three or more second redistribution patterns 630 may be stacked.

The second seed pads 655 may be disposed between the uppermost second redistribution patterns 630 and the second redistribution pads 650. The second seed pads 655 may include a conductive seed material.

The semiconductor package 10 may further include bridge connection portions 570. The bridge connection portions 570 may be disposed between the bridge structures 500, and may be electrically connected to the bridge structures 500 and the second substrate 600. The bridge connection portions 570 may be disposed on the second conductive pads 552. The corresponding second redistribution patterns 630, among the second redistribution patterns 630, may be connected to the bridge connections 570 on the bridge connection portions 570. Accordingly, the second substrate 600 may be electrically connected to the first substrate 100 via the bridge structures 500. For example, the bridge structures 500 may provide vertical electrical paths between the first substrate 100 and the second substrate 600. The vertical electrical path may include a signal path. The bridge connection portions 570 may include metal vias or metal studs. The bridge connection portions 570 may include, for example, copper, titanium, tungsten, silver (Ag), gold (Au), nickel, and/or a combination thereof.

The first upper semiconductor chips 230 may be disposed on the upper surface of the second substrate 600. The first upper semiconductor chips 230 may be spaced apart from the first lower semiconductor chip 210, in a plan view, and might not overlap the first lower semiconductor chip 210, in a plan view. The first upper semiconductor chips 230 may be spaced apart from the first lower semiconductor chip 210 in a diagonal direction as illustrated in FIG. 1B. The diagonal direction may cross the first direction, the second direction, and the third direction. The first upper semiconductor chips 230 may perform different functions from the first lower semiconductor chip 210, but are not necessarily limited thereto. The first upper semiconductor chips 230 may transceive (e.g., send and/or receive) electrical signals with the first lower semiconductor chip 210 via the bridge structures 500. The electrical signal may include a data signal or a processing signal.

According to some embodiments of the present disclosure, the bridge structures 500 may be respectively disposed between the first lower semiconductor chip 210 and the first upper semiconductor chips 230, in a plan view, as illustrated in FIG. 1A. Accordingly, the length of an electrical signal path between the first lower semiconductor chip 210 and the first upper semiconductor chips 230 may be shortened. A high-speed signal transfer between the first lower semiconductor chip 210 and the first upper semiconductor chips 230 may be facilitated. The total number of bridge structures 500 may be the same as the total number of first upper semiconductor chips 230.

The first upper semiconductor chips 230 may be vertically spaced apart from the upper surfaces of the second lower semiconductor chips 220. The first upper semiconductor chips 230 may overlap the second lower semiconductor chips 220, in a plan view. The total number of first upper semiconductor chips 230 may be the same as the total number of second lower semiconductor chips 220, but is not necessarily limited thereto.

As illustrated in FIG. 1B, each of the first upper semiconductor chips 230 may include third chip pads 235, a third semiconductor die, and a third integrated circuit layer. A lower surface of the third semiconductor die may face the second substrate 600. The third integrated circuit layer may include third insulating layers, third conductive wirings, and third integrated circuits. The third integrated circuits may include logic circuits, and may be disposed under a lower surface of the third semiconductor die. Alternatively, the third integrated circuits may include memory circuits. The third insulating layers may be stacked under the lower surfaces of the third semiconductor die. Any one of the third insulating layers may cover the third integrated circuits. The third conductive wirings may be disposed between the third insulating layers and may be electrically connected to the third integrated circuits. The third chip pads 235 may be disposed on the lower surface of a third lower semiconductor chip. The third chip pads 235 may be electrically connected to the third integrated circuits via the third conductive wirings. The third chip pads 235 may include a metal such as aluminum.

The semiconductor package 10 may further include first conductive bumps 274. The first conductive bumps 274 may be disposed between the second substrate 600 and the first upper semiconductor chips 230. For example, the first conductive bumps 274 may be disposed between the corresponding second redistribution pads 650 and the third chip pads 235, and may be connected to the second redistribution pads 650 and the third chip pads 235. The first conductive bumps 274 may include solder balls. The first conductive bumps 274 may further include filler patterns. The first upper semiconductor chips 230 may be electrically connected to the second substrate 600 via the first conductive bumps 274. Accordingly, the first upper semiconductor chips 230 may be electrically connected to the first lower semiconductor chip 210 via the second substrate 600, the bridge structures 500, and the first substrate 100. The conductive vias 550 of the bridge structures 500 may include signal vias. For example, the conductive vias 550 may transfer electrical signals between the first lower semiconductor chip 210 and the first upper semiconductor chips 230.

According to some embodiments of the present disclosure, because the semiconductor package 10 includes the first upper semiconductor chips 230, a sum of plan areas of semiconductor chips included in the semiconductor package 10 may increase. The sum of plan areas of the semiconductor chips may include a sum of a plan area of the first lower semiconductor chip 210, a plan area of the second lower semiconductor chips 220, and a plan area of the first upper semiconductor chips 230. As the sum of plan areas of the semiconductor chips increases, performance of the semiconductor package 10 may be increased.

According to some embodiments of the present disclosure, because the first upper semiconductor chips 230 overlaps the second lower semiconductor chips 220, in a plan view, the plan area of the semiconductor package 10 may be reduced. According to some embodiments of the present disclosure, although the sum of plan areas of the semiconductor chips included in the semiconductor package 10 increases, the semiconductor package 10 may be miniaturized.

The first upper semiconductor chips 230 may be electrically connected to the conductive posts 300 via the second substrate 600. The second pitch P2 of the conductive posts 300 may be relatively large. The first upper semiconductor chips 230 may receive a voltage via the conductive post 300. The voltage may be a power voltage or a ground voltage. According to some embodiments of the present disclosure, because the conductive post 300 functions as a voltage supply path with the second pitch P2, a voltage may be stably supplied to the first upper semiconductor chips 230. When the conductive posts 300 are used as signal transmission paths between the first lower semiconductor chip 210 and the first upper semiconductor chips 230, the length of the signal transmission path between the first lower semiconductor chip 210 and the first upper semiconductor chips 230 may increase. According to some embodiments of the present disclosure, because the conductive vias 550 of the bridge structures 500 are used as the signal transmission paths between the first lower semiconductor chip 210 and the first upper semiconductor chips 230, a high-speed signal transfer between the first lower semiconductor chip 210 and the first upper semiconductor chips 230 may be possible. According to some embodiments of the present disclosure, the first pitch P1 of the conductive vias 550 may be relatively small. The first pitch P1 may be less than the second pitch P2. For example, because the first pitch P1 of the conductive vias 550 is about 5 μm or less, the signal transmission between the first lower semiconductor chip 210 and the first upper semiconductor chips 230 may be appropriate for a high performance processing such as artificial intelligence (AI).

The semiconductor package 10 may further include first underfill patterns 434. The first underfill patterns 434 may be disposed on fourth gap regions between the second substrate 600 and the first upper semiconductor chips 230 and cover sidewalls of the first conductive bumps 274. The first underfill patterns 434 may include insulating polymer such as epoxy polymer.

The second molding layer 420 may be disposed on the second substrate 600 and cover the first upper semiconductor chips 230. The second molding layer 420 may include insulating polymer such as epoxy-based molding compound. The second molding layer 420 may include a different material from the first underfill patterns 434. The first underfill patterns 434 may be omitted, and the second molding layer 420 may further extend to lower surfaces of the first upper semiconductor chips 230 to cover the sidewalls of the first conductive bumps 274.

Hereinafter, transmission of electrical signals of the first lower semiconductor chip, the second lower semiconductor chips, and the first upper semiconductor chips is described. To the extent that an element is not described in detail with respect to this figure, it may be understood that the element is at least similar to a corresponding element that has been described elsewhere within the present disclosure.

FIG. 1C is a diagram illustrating the transmission of electrical signals between the first lower semiconductor chip, the second lower semiconductor chips, and the first upper semiconductor chips, according to an embodiment of the present disclosure.

As used herein, the term “chiplet” may mean a smaller integrated circuit (IC) that contains a well-defined subset of functionality that may be combined with other chiplets on an interposer in a single package. Referring to FIG. 1C, together with FIGS. 1A and 1B, the first lower semiconductor chip 210 may include a first lower chiplet. For example, the first lower semiconductor chip 210 may include a core chiplet or a hub chiplet. A chiplet may include intellectual property (IP) block units formed by dividing a logic semiconductor chip with respect to functions. The logic semiconductor chip may constitute one processor, and may function as one processor. Unlike this case, each chiplet might not operate as an independent processor, but the chiplets may be connected to each other to operate as at least one processor. The processor may include chiplets connected to each other.

According to some embodiments of the present disclosure, the first integrated circuits of the first lower semiconductor chip 210 may form at least one IP block unit. When the first lower semiconductor chip 210 includes a chiplet, the IP block unit of the first lower semiconductor chip 210 may include first communication IP units. The first lower semiconductor chip 210 may transceiver (e.g., send and/or receive) signals to and from another semiconductor chip or another chiplet via the first communication IP units. The first communication IP units may include die to die (D2D) IPs. The first communication IP units might not include cache coherent interconnect for accelerators (CCIX), but are not necessarily limited thereto.

The second lower semiconductor chips 220 may include second lower chiplets. The second integrated circuits of each of the second lower semiconductor chips 220 may form at least one IP block unit. As an example, the IP block unit of the second lower semiconductor chips 220 may perform a different function from the IP block unit of the first lower chiplet, or may have a different design from the IP block unit. Any one IP block unit among the second lower semiconductor chips 220 may perform the same or different function as or from any other IP block unit among the second lower semiconductor chips 220, or may have the same or different design as or from any other IP block unit among the second lower semiconductor chips 220. When the second lower semiconductor chips 220 include chiplets, the IP block unit of each of the second lower semiconductor chips 220 may include a second communication IP unit. The second communication IP units may include the D2D IPs. Each of the second lower semiconductor chips 220 may transceive (e.g., send and/or receive) signals to and from other semiconductor chip or other chiplet via the second communication IP unit.

The first upper semiconductor chips 230 may include first upper chiplets. The third integrated circuits of each of the first upper semiconductor chips 230 may form at least one IP block unit. For example, the IP block units of the first upper semiconductor chips 230 may perform a different function, and have a different design from the IP block unit of the first lower semiconductor chip 210. The IP block unit of the first upper semiconductor chips 230 may perform the same or different function as or from the IP block units of the second lower semiconductor chips 220, or may have the same or different design as or from the IP block units of the second lower semiconductor chips 220. Any one IP block unit among the first upper semiconductor chips 230 may perform the same or different function as or from any other IP block unit among the first upper semiconductor chips 230, or may have the same or different design as or from any other IP block unit among the first upper semiconductor chips 230. When the first upper semiconductor chips 230 include chiplets, the IP block unit of each of the first upper semiconductor chips 230 may include a third communication IP unit. Each of the first upper semiconductor chips 230 may transceive (e.g., send and/or receive) signals to and from other semiconductor chip or other chiplet via the third communication IP unit. The third communication IP units may include D2D IPs.

The first upper semiconductor chips 230 and the second lower semiconductor chips 220 may be electrically connected to the first lower semiconductor chip 210. When each of the first lower semiconductor chip 210, the second lower semiconductor chips 220, and the first upper semiconductor chips 230 is a chiplet, the first lower semiconductor chip 210, the second lower semiconductor chips 220, and the first upper semiconductor chips 230 may constitute one processor. The processor may include, for example, a central processing unit (CPU), a graphics processing unit (GPU), a data processing unit (DPU), and/or a neural processing unit (NPU). In this case, first communication IP units may respectively contact second communication IP units, and the first lower semiconductor chip 210 may be respectively and electrically connected to the second lower semiconductor chips 220. The first communication IP units may respectively contact third communication IP units, and the first lower semiconductor chip 210 may be respectively and electrically connected to the first upper semiconductor chips 230. Arrows in FIG. 1C may schematically represent an electrical connection between the first lower semiconductor chip 210 and the second lower semiconductor chips 220 and an electrical connection between the first lower semiconductor chip 210 and the first upper semiconductor chips 230. The arrow of FIG. 1C may correspond to a radix of the first lower semiconductor chip 210. The radix of the first lower semiconductor chip 210 may be the same as the number of semiconductor chips/chiplets which are electrically connected to the first lower semiconductor chip 210 without passing through another semiconductor chip or another chiplet. For example, when a certain chiplet/semiconductor chip is electrically connected to the first lower semiconductor chip 210 without passing through another chiplet/semiconductor chip and with passing through the first substrate 100, and the second substrate 600 in FIG. 1 or at least one bridge structure 500, an electrical connection between the chiplet/semiconductor chip and the first lower semiconductor chip 210 may correspond to the radix. When a certain chiplet/semiconductor chip is electrically connected to the first lower semiconductor chip 210 via another chiplet/semiconductor chip, a bottleneck phenomenon may occur in a process of electrically connecting the certain chiplet/semiconductor chip to the first lower semiconductor chip 210.

According to some embodiments of the present disclosure, not only the second lower semiconductor chips 220 but the first upper semiconductor chips 230 may be electrically connected to the first lower semiconductor chip 210. For example, the first upper semiconductor chips 230 may, as illustrated in FIG. 1B, be electrically connected to the first lower semiconductor chip 210 via the bridge structures 500. Because the first upper semiconductor chips 230 are connected to the first lower semiconductor chip 210 without passing through another chiplet/semiconductor chip, the radix of the first lower semiconductor chip 210 may increase. The bottleneck phenomenon in an electrical connection between the first upper semiconductor chips 230 and the first lower semiconductor chip 210 may be reduced or avoided. According to some embodiments of the present disclosure, because the radix of the first lower semiconductor chip 210 increases, the semiconductor package 10 may have reduced signal latency, low power consumption, and increased bandwidth. As an example, although it is illustrated in FIG. 1C that the first lower semiconductor chip 210 is electrically connected to four second lower semiconductor chips 220 and four first upper semiconductor chips 230, and accordingly, the radix of the first lower semiconductor chip 210 is eight, the number of chiplets/semiconductor chips electrically connected to the first lower semiconductor chip 210 and the radix of the first lower semiconductor chip 210 are not necessarily limited thereto, and may be variously modified.

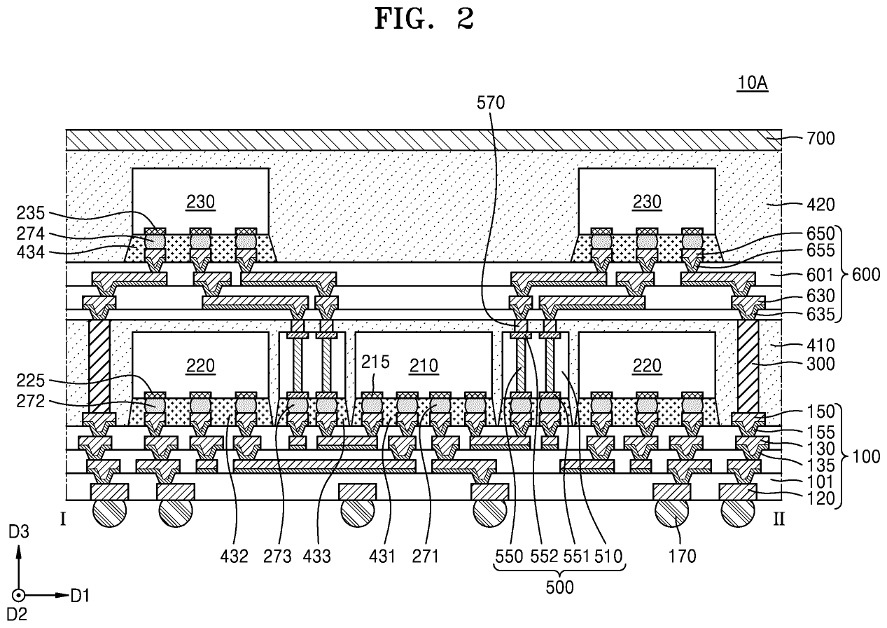

FIG. 2 is a diagram of a semiconductor package 10A, according to an embodiment, and may correspond to a cross-section taken along line I-II in FIG. 1A. To the extent that an element is not described in detail with respect to this figure, it may be understood that the element is at least similar to a corresponding element that has been described elsewhere within the present disclosure.

Referring to FIG. 2 together with FIG. 1A, the semiconductor package 10A may include the first substrate 100, the solder ball terminals 170, the first lower semiconductor chip 210, the second lower semiconductor chips 220, the bridge structure 500, the conductive posts 300, the first molding layer 410, the second substrate 600, the second molding layer 420, the first upper semiconductor chips 230, and in addition, a heat dissipation structure 700. The second molding layer 420 and the first upper semiconductor chips 230 may be substantially the same as described with reference to embodiments of FIGS. 1A through IC. However, the upper surface of the second molding layer 420 may be disposed at the substantially same level as the upper surfaces of the first upper semiconductor chips 230. A level of a component may mean a vertical level.

The heat dissipation structure 700 may be disposed above the upper surfaces of the first upper semiconductor chips 230. The heat dissipation structure 700 may further extend onto the upper surface of the second molding layer 420. The heat dissipation structure 700 may include a heat sink, a heat slug, or a thermal interface material (TIM) layer. The heat dissipation structure 700 may include, for example, a metal. During an operation of the semiconductor package 10A, heat generated by the first upper semiconductor chips 230 may be emitted fast to the outside via the heat dissipation structure 700.

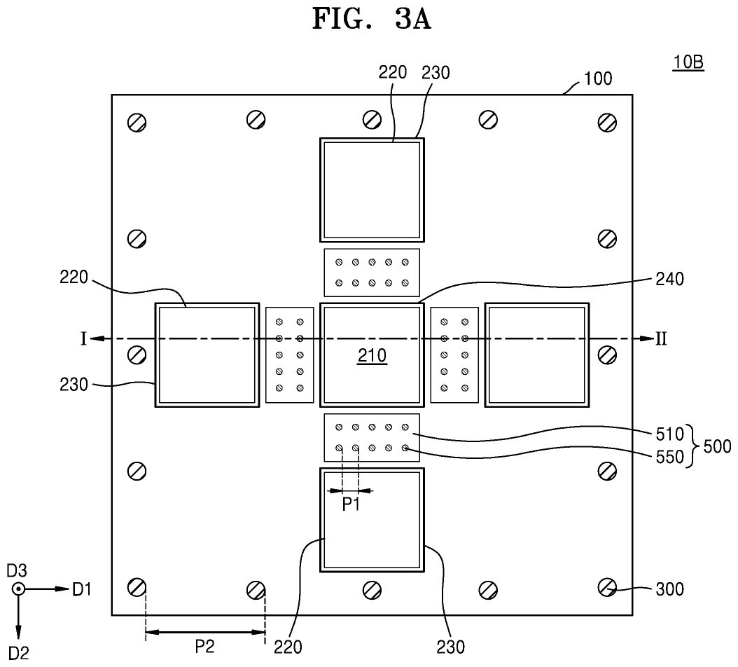

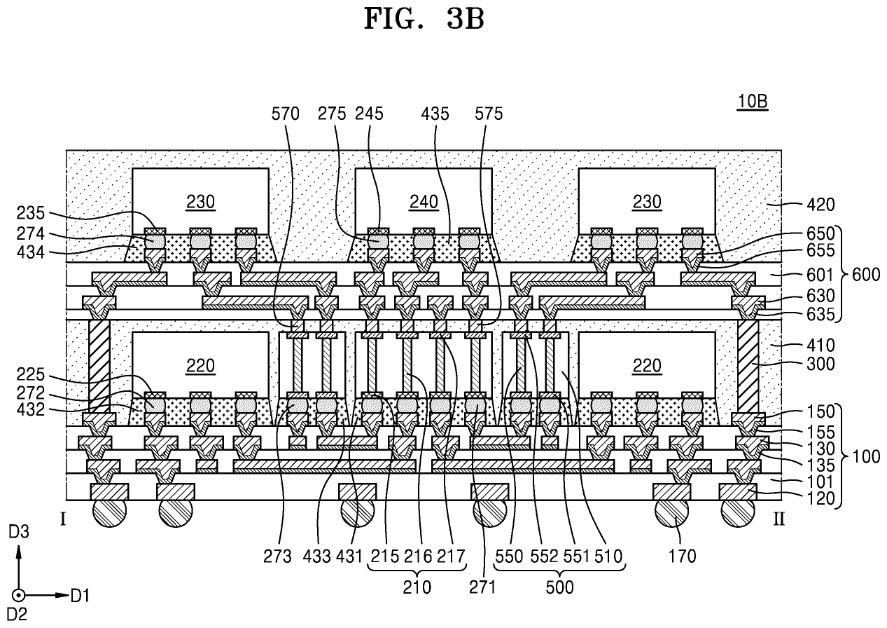

FIG. 3A is a plan view of a semiconductor package 10B according to an embodiment of the present disclosure. FIG. 3B is a cross-sectional view of the semiconductor package 10B taken along line I-II in FIG. 3A.

Referring to FIGS. 3A and 3B, the semiconductor package 10B may include the first substrate 100, the solder ball terminals 170, the first lower semiconductor chip 210, the second lower semiconductor chips 220, the bridge structure 500, the conductive posts 300, the first molding layer 410, the second substrate 600, the second molding layer 420, the first upper semiconductor chips 230, and in addition, a second upper semiconductor chip 240.

The first lower semiconductor chip 210 may be the same as or similar to descriptions given with reference to embodiments of FIGS. 1A through IC. However, the first lower semiconductor chip 210 may include the first chip pads 215, the first semiconductor die, the first integrated circuit layer, and in addition, first through vias 216 and upper pads 217. The first through vias 216 may penetrate the first semiconductor die of the first lower semiconductor chip 210. The first through vias 216 may be electrically connected to the first chip pads 215 or the first integrated circuits. The upper pads 217 may be exposed on the upper surface of the first lower semiconductor chip 210, and may be in contact with the first through vias 216.

The semiconductor package 10B may further include chip connection portions 575. The chip connection portions 575 may be disposed between the first lower semiconductor chip 210 and the second substrate 600, and may be electrically connected to the first lower semiconductor chip 210 and the second substrate 600. For example, the chip connection portions 575 may be respectively disposed on the upper pads 217. The corresponding second redistribution patterns 630 may be in contact with the chip connection portions 575. Accordingly, the second substrate 600 may be electrically connected to the first lower semiconductor chip 210 via the chip connection portions 575. The chip connection portions 575 may include metal vias or metal studs. The chip connection portions 575 may include, for example, copper, titanium, tungsten, Ag, Au, nickel, and/or a combination thereof.

The second upper semiconductor chip 240 may be disposed on the second substrate 600, and may be laterally spaced apart from the first upper semiconductor chips 230. The second upper semiconductor chip 240 may be disposed between the first upper semiconductor chips 230. The second upper semiconductor chip 240 may overlap the first lower semiconductor chip 210, in a plan view, as illustrated in FIG. 3A. Accordingly, although the semiconductor package 10B includes the second upper semiconductor chip 240, the semiconductor package 10B may be miniaturized. According to some embodiments of the present disclosure, because the semiconductor package 10B includes the second upper semiconductor chip 240, a sum of plan area of semiconductor chips included in the semiconductor package 10B may increase. A sum of plan area of the semiconductor chips may include a sum of the plan area of the first lower semiconductor chip 210, the plan area of the second lower semiconductor chips 220, the plan area of the first upper semiconductor chips 230, and a plan area of the second upper semiconductor chip 240. Accordingly, performance of the semiconductor package 10B may be increased.

Each of the second upper semiconductor chips 240 may, as illustrated in FIG. 3B, include fourth chip pads 245, a fourth second semiconductor die, and a fourth integrated circuit layer. A lower surface of the fourth semiconductor die may face the second substrate 600. The fourth integrated circuit layer may include fourth insulating layers, fourth conductive wirings, and fourth integrated circuits. The fourth integrated circuits may include logic circuits, and may be disposed under the lower surface of the fourth semiconductor die. Alternatively, the fourth integrated circuits may include memory circuits. The fourth insulating layers may be stacked under the lower surfaces of the fourth semiconductor die. Any one of the fourth insulating layers may cover the fourth integrated circuits. The fourth conductive wirings may be disposed between the fourth insulating layers, and may be connected to the fourth integrated circuits. The fourth chip pads 245 may be disposed on the lower surface of the second upper semiconductor chip 240. The lower surface of the second upper semiconductor chip 240 may include the lower surface of the second integrated circuit layer. The fourth chip pads 245 may be electrically connected to the fourth integrated circuits via the fourth conductive wirings. The fourth chip pads 245 may include a metal such as aluminum.

The semiconductor package 10B may further include second conductive bumps 275. The second conductive bumps 275 may be disposed between the second substrate 600 and the second upper semiconductor chip 240. For example, the second conductive bumps 275 may be disposed between the second redistribution pads 650 and the fourth chip pads 245, which correspond to the second conductive bumps 275, and may be connected to the second redistribution pads 650 and the fourth chip pads 245. The second conductive bumps 275 may include solder balls. The second conductive bumps 275 may further include filler patterns. The second upper semiconductor chip 240 may be electrically connected to the second substrate 600 via the second conductive bumps 275. Accordingly, the second upper semiconductor chip 240 may be electrically connected to the first integrated circuits of the first lower semiconductor chip 210 via the second substrate 600, the chip connection portions 575, and through vias 216. The second upper semiconductor chip 240 may transceive (e.g., send and/or receive) data signals or electrical signals such as a processing signal to and from the first lower semiconductor chip 210. As an example, the second upper semiconductor chip 240 may perform different functions from the first lower semiconductor chip 210.

According to an embodiment of the present disclosure, the second upper semiconductor chip 240 may include a second upper chiplet. The fourth integrated circuits of the second upper semiconductor chips 240 may form at least one IP block unit. For example, the IP block unit of the second upper semiconductor chips 240 may perform a different function, and have a different design from the IP block unit of the first lower semiconductor chip 210. The IP block units of the second upper semiconductor chips 240 may perform the same or different function as or from the IP block units of the first upper semiconductor chips 230, or may have the same or different design as or from the IP block units of the first upper semiconductor chips 230. The IP block units of the second upper semiconductor chip 240 may perform the same or different function as or from the IP block units of the second lower semiconductor chips 220, or may have the same or different design as or from the IP block units of the second lower semiconductor chips 220. When the second upper semiconductor chip 240 includes a chiplet, the IP block unit of the second upper semiconductor chip 240 may include a fourth communication IP units. The fourth communication IP units may include the D2D IPs. The through vias 216 may function as a signal transfer path between the first communication IP unit of the first lower semiconductor chip 210 and the fourth communication IP unit of the second upper semiconductor chip 240.

According to some embodiments of the present disclosure, the first lower semiconductor chip 210, the second lower semiconductor chips 220, the first upper semiconductor chips 230, and the second upper semiconductor chip 240 may constitute one processor. Because the second upper semiconductor chip 240 is connected to the first lower semiconductor chip 210 without passing through other chiplet/semiconductor chip, the radix of the first lower semiconductor chip 210 may increase. The semiconductor package 10B may have reduced signal latency, low power consumption, and increased bandwidth.

The second upper semiconductor chip 240 may be electrically connected to at least one of the conductive posts 300 via the second substrate 600. The second upper semiconductor chip 240 may receive a voltage via the at least one conductive post 300. The voltage may be a power voltage or a ground voltage. When the conductive posts 300 are used as signal transmission paths between the first lower semiconductor chip 210 and the second upper semiconductor chip 240, the length of the signal transmission path between the first lower semiconductor chip 210 and the second upper semiconductor chip 240 may increase. According to some embodiments of the present disclosure, because the conductive post 300 functions as a voltage supply path with the second pitch P2, a voltage may be stably supplied to the second upper semiconductor chip 240.

According to some embodiments of the present disclosure, because the second upper semiconductor chip 240 overlaps the first lower semiconductor chip 210 in a plan view, and the second upper semiconductor chip 240 is electrically connected to the first integrated circuits of the first lower semiconductor chip 210 via the chip connection portions 575 and the through vias 216, the length of the signal transmission path between the first lower semiconductor chip 210 and the second upper semiconductor chip 240. Accordingly, signal transfer between the first lower semiconductor chip 210 and the second upper semiconductor chip 240 may be performed at a high speed. The signal transmission between the first lower semiconductor chip 210 and the second upper semiconductor chip 240 may be appropriate for a high performance processing such as AI.

The semiconductor package 10B may further include a second underfill pattern 435. The second underfill pattern 435 may be disposed in a fifth gap region between the second substrate 600 and the second upper semiconductor chip 240, and may cover the sidewalls of the second conductive bumps 275. The second underfill pattern 435 may include insulating polymer such as epoxy polymer.

The second molding layer 420 may cover the sidewalls of the second upper semiconductor chip 240. The second underfill pattern 435 may be omitted, and the second molding layer 420 may further extend to the lower surface of the second upper semiconductor chip 240 and may cover the sidewalls of the second conductive bumps 275.

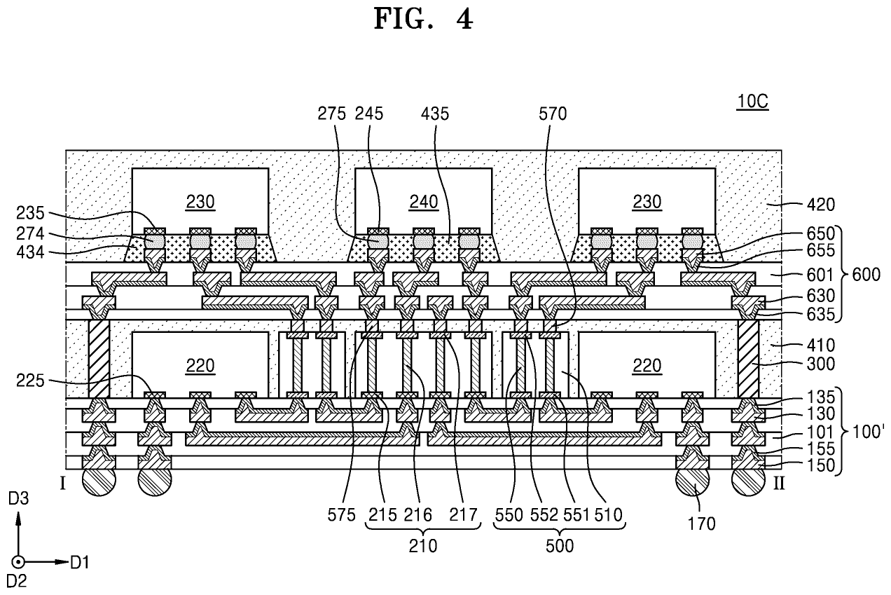

FIG. 4 is a diagram of a semiconductor package 10C according to an embodiment of the present disclosure, and may correspond to a cross-section taken along line I-II in FIG. 3A.

Referring to FIG. 4 together with FIG. 3A, the semiconductor package 10C may include a first substrate 100′, the solder ball terminals 170, the first lower semiconductor chip 210, the second lower semiconductor chips 220, the bridge structures 500, the conductive posts 300, the first molding layer 410, the second substrate 600, the second molding layer 420, the first upper semiconductor chips 230, and the second upper semiconductor chip 240. However, the semiconductor package 10C might not include the first lower bumps 271, the second lower bumps 272, the third lower bumps 273, and the first through third underfill layers 431 through 433, which have been described with reference to FIG. 1B.

The first substrate 100′ may include a redistribution substrate. The first substrate 100′ may include the first insulating layers 101, the first redistribution patterns 130, the first seed patterns 135, the first seed pads 155, and the first redistribution pads 150. However, the first substrate 100′ might not include the under bump patterns 120 described with reference to FIG. 1B. The first substrate 100′ may be in direct contact with the first lower semiconductor chip 210, the second lower semiconductor chips 220, the bridge structures 500, and the first molding layer 410. For example, the uppermost first insulating layer 101 may be in direct contact with a lower surface of the first lower semiconductor chip 210, lower surfaces of the second lower semiconductor chips 220, lower surfaces of the bridge structure 500, and the lower surface of the first molding layer 410. The first seed patterns 135 may be respectively disposed on upper surfaces of the first redistribution patterns 130. The first seed patterns 135 in the uppermost first insulating layer 101 may be in contact with the first chip pads 215, the second chip pads 225, the first conductive pads 551, or the conductive posts 300. The first seed patterns 135 may be respectively disposed on the upper surfaces of the first redistribution patterns 130.

The semiconductor package 10C may be manufactured using a chip-first process, but is not necessarily limited thereto.

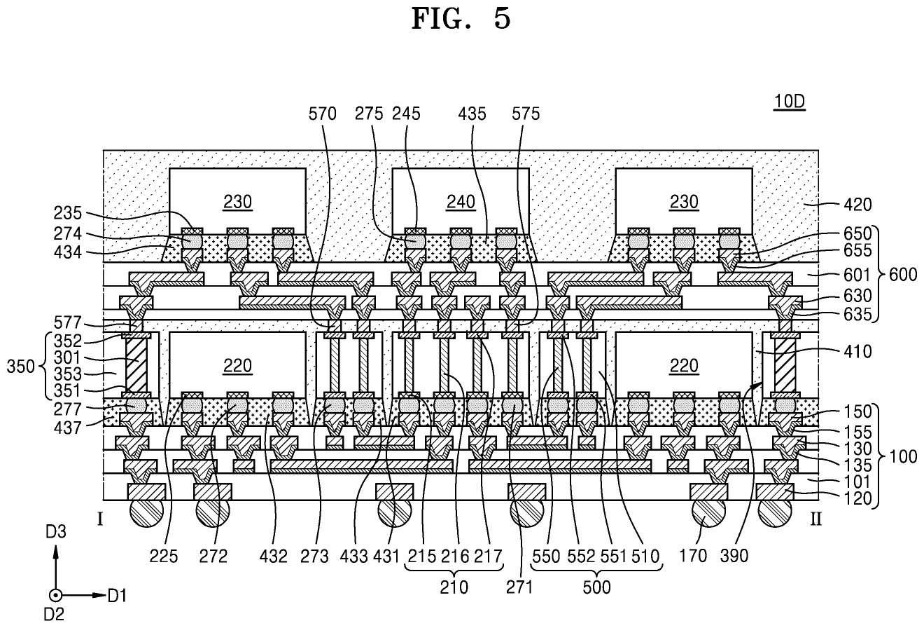

FIG. 5 is a diagram of a semiconductor package 10D according to an embodiment, of the present disclosure, and may correspond to a cross-section taken along line I-II in FIG. 3A. To the extent that an element is not described in detail with respect to this figure, it may be understood that the element is at least similar to a corresponding element that has been described elsewhere within the present disclosure.

Referring to FIG. 5 together with FIG. 3A, the semiconductor package 10D may include the first substrate 100, the solder ball terminals 170, the first lower semiconductor chip 210, the second lower semiconductor chips 220, a connection substrate 350, the bridge structures 500, the first molding layer 410, the second substrate 600, the second molding layer 420, the first upper semiconductor chips 230, and the second upper semiconductor chip 240. The semiconductor package 10D may further include fourth lower bumps 237, a fourth underfill layer 437, and a conductive connection portion 577.

The connection substrate 350 may be disposed on an upper surface of an edge region of the first substrate 100. The connection substrate 350 may include a substrate hole 390 penetrating the inside of the connection substrate 350. As an example, by forming the substrate hole 390 penetrating an upper surface and a lower surface of a printed circuit board, the connection substrate 350 may be manufactured. The first lower semiconductor chip 210, the second lower semiconductor chips 220, and the bridge structures 500 may be disposed in the substrate hole 390 of the connection substrate 350. The second lower semiconductor chips 220 may be spaced apart from inner sidewalls of the connection substrate 350.

The connection substrate 350 may include a base layer 353 and a conductive structure 301. The base layer 353 may include an insulating material. The base layer 353 may include, for example, a carbon-based material, ceramic, or polymer. The conductive structure 301 may be disposed in the base layer 353. The connection substrate 350 may further include a first pad 351 and a second pad 352. The first pad 351 may be disposed on a lower surface of the conductive structure 301, and may be in contact with the conductive structure 301. The second pad 352 may be disposed on the conductive structure 301, and may be in contact with the conductive structure 301. The second pad 352 may be exposed on an upper surface of the base layer 353. The conductive structure 301, the first pad 351, and the second pad 352 may include a metal. The conductive structure 301 may be provided in plural, and the plurality of conductive structures 301 may be electrically separate from each other. The conductive structures 301 may include, for example, copper, aluminum, tungsten, titanium, iron, and/or an alloy thereof.

The conductive structures 301 may be the same as or similar to the conductive posts 300 described with reference to embodiments of FIGS. 1A and 1B or FIGS. 3A and 3B. For example, the conductive structures 301 may have substantially the same electrical connection as the conductive posts 300 described with reference to embodiments of FIGS. 1A and 1B or FIGS. 3A and 3B. For example, the first upper semiconductor chips 230 and the second upper semiconductor chip 240 may be electrically connected to the conductive structures 301 via the second substrate 600. The first upper semiconductor chips 230 and the second upper semiconductor chip 240 may receive a voltage via the conductive posts 300. Accordingly, a voltage may be stably supplied to the first upper semiconductor chips 230 and the second upper semiconductor chip 240. The conductive structures 301 might not be used as a signal transmission path. Hereinafter, one single conductive structure 301 is described.

A fourth lower bump 277 may be disposed between the first substrate 100 and the connection substrate 350. The fourth lower bump 277 may be disposed between the first pad 351 and the corresponding first redistribution pad 150, and may be in contact with the first pad 351 and the first redistribution pad 150 corresponding thereto. The conductive structure 301 may be electrically connected to the first substrate 100 via the fourth lower bump 277. The fourth lower bump 277 may include at least one of the solder balls and the filler patterns. The fourth lower bump 277 may include a metal.

The forth underfill layer 437 may be disposed in gaps between the first substrate 100 and the connection substrate 350 and may encapsulate the fourth lower bumps 277. The forth underfill layer 437 may include insulating polymer.

The conductive connection portion 577 may be disposed between a connection substrate 250 and the second substrate 600, and may be electrically connected to the connection substrate 250 and the second substrate 600. For example, the conductive connection portion 577 may be disposed on the second pad 352. The corresponding second redistribution pattern 630, among the second redistribution patterns 630, may be connected to the conductive connection portion 577. Accordingly, the second substrate 600 may be electrically connected to the conductive structure 301 via the conductive connection portion 577. The conductive connection portion 577 may include, for example, metal vias or metal studs. The conductive connection portion 577 may include, for example, copper, titanium, tungsten, Ag, Au, nickel, and/or a combination thereof.

Embodiments of the inventive concept may be combined with each other. The embodiments of the semiconductor package 10 of FIGS. 1A through IC, the embodiment of the semiconductor package 10A of FIG. 2, the embodiments of the semiconductor package 10B of FIGS. 3A and 3B, the embodiment of the semiconductor package 10C of FIG. 4, and the embodiment of the semiconductor package 10D of FIG. 5 may be combined with each other. For example, the semiconductor package 10B of FIGS. 3A and 3B, the semiconductor package 10C of FIG. 4, and the semiconductor package 10D of FIG. 5 may further include the heat dissipation structure 700 described with reference to FIG. 2. Alternatively, the semiconductor package 10 of FIGS. 1A through 1C or the semiconductor package 10D of FIG. 5 may include the first substrate 100′ as described in the embodiment of FIG. 4. The embodiments may be variously combined.

While the inventive concept has been particularly shown and described with reference to embodiments thereof, it will be understood that various changes in form and details may be made therein without departing from the spirit and scope of the present disclosure.

What is claimed is:

1. A semiconductor package, comprising:
a first substrate;
a first lower semiconductor chip disposed on the first substrate;
a bridge structure disposed on the first substrate and laterally spaced apart from the first lower semiconductor chip;
a second substrate disposed on the first lower semiconductor chip and the bridge structure; and
a first upper semiconductor chip disposed on the second substrate,
wherein the first upper semiconductor chip is spaced apart from the first lower semiconductor chip,
wherein the bridge structure comprises:
a base structure; and
conductive vias disposed in the base structure and contacting the first substrate, and
wherein the first upper semiconductor chip is electrically connected to the first lower semiconductor chip through the conductive vias.

2. The semiconductor package of claim 1, wherein the bridge structure is disposed between the first lower semiconductor chip and the first upper semiconductor chip.

3. The semiconductor package of claim 1,
further comprising a second lower semiconductor chip disposed on the first substrate and laterally spaced apart from the first lower semiconductor chip,
wherein the bridge structure is disposed between the first lower semiconductor chip and the second lower semiconductor chip.

4. The semiconductor package of claim 3, wherein a distance between the first lower semiconductor chip and the second lower semiconductor chip is about 50 μm to about 2 mm.

5. The semiconductor package of claim 3, wherein one sidewall of the second lower semiconductor chip faces a first sidewall of the first lower semiconductor chip.

6. The semiconductor package of claim 5, wherein a length of the one sidewall of the second lower semiconductor chip and a length of the first sidewall of the first lower semiconductor chip are equal to each other or have a difference of about 10 μm or less.

7. The semiconductor package of claim 1,
further comprising conductive posts laterally spaced apart from the first lower semiconductor chip, on an upper surface of the first substrate,
wherein the conductive vias have a first pitch,
wherein the conductive posts have a second pitch, and
wherein the first pitch is less than the second pitch.

8. The semiconductor package of claim 7,
wherein the conductive vias comprise signal vias, and
wherein a voltage is configured to supply to the conductive post.

9. The semiconductor package of claim 1,
wherein the first lower semiconductor chip comprises a first chiplet, and
wherein the first upper semiconductor chip comprises a second chiplet.

10. The semiconductor package of claim 1,
further comprising a second upper semiconductor chip disposed on the second substrate, and vertically spaced apart from an upper surface of the first lower semiconductor chip,
wherein the first lower semiconductor chip further comprises through vias penetrating an inside thereof, and
wherein the second upper semiconductor chip is electrically connected to the through vias by the second substrate.

11. The semiconductor package of claim 1,
wherein the first upper semiconductor chip is provided in plural,
wherein the bridge structure is provided in plural, and
wherein the number of the plurality of first upper semiconductor chips is equal to the number of the plurality of bridge structures.

12. The semiconductor package of claim 1,
further comprising a molding layer disposed between the first substrate and the second substrate,
wherein the molding layer covers sidewalls of the base structure, and is spaced apart from the conductive vias.

13. A semiconductor package, comprising:
a first substrate;
a first lower chiplet disposed on the first substrate;
a second lower chiplet disposed on the first substrate and laterally spaced apart from the first lower chiplet;
a bridge structure disposed on the first substrate, between the first lower chiplet and the second lower chiplet;
a second substrate disposed on the second lower chiplet and the bridge structure; and
a first upper chiplet disposed on the second substrate,
wherein the first upper chiplet is electrically connected to the first lower chiplet via the second substrate and the bridge structure.

14. The semiconductor package of claim 13, wherein the first upper chiplet is spaced apart from the first lower chiplet.

15. The semiconductor package of claim 13,
wherein the second lower chiplet comprises a first edge chiplet, a second edge chiplet, a third edge chiplet, and a fourth edge chiplet, and
wherein one sidewall of the first edge chiplet faces a first sidewall of the first lower chiplet, and is spaced apart from the first sidewall of the first lower chiplet,
wherein one sidewall of the second edge chiplet faces a second sidewall of the first lower chiplet, and is spaced apart from the second sidewall of the first lower chiplet,
wherein one sidewall of the third edge chiplet faces a third sidewall of the first lower chiplet, and is spaced apart from the third sidewall of the first lower chiplet, and
wherein one sidewall of the fourth edge chiplet faces a fourth sidewall of the first lower chiplet, and is spaced apart from the fourth sidewall of the first lower chiplet.

16. The semiconductor package of claim 15,
wherein the one sidewall of the first edge chiplet extends parallel to the first sidewall of the first lower chiplet,
wherein the one sidewall of the second edge chiplet extends parallel to the second sidewall of the first lower chiplet,
wherein the one sidewall of the third edge chiplet extends parallel to the third sidewall of the first lower chiplet, and
wherein the one sidewall of the fourth edge chiplet extends parallel to the fourth sidewall of the first lower chiplet.

17. A semiconductor package, comprising:
a first rewiring substrate including a first insulating layer, a first seed pattern, and a first conductive pattern disposed on the first seed pattern, wherein the first insulating layer comprises photo sensitive polymer;
a first lower semiconductor chip disposed on an upper surface of the first redistribution substrate;
second lower semiconductor chips disposed on the upper surface of the first redistribution substrate and laterally spaced apart from the first lower semiconductor chip;
bridge structures respectively disposed on the upper surface of the first redistribution substrate, between the first lower semiconductor chip and the second lower semiconductor chips;
conductive structures disposed on the upper surface of the first redistribution substrate and laterally spaced apart from the second lower semiconductor chips;
a first molding layer disposed on the upper surface of the first redistribution substrate and covering the first lower semiconductor chip, the second lower semiconductor chips, and the bridge structures;
a second redistribution substrate disposed on the first molding layer and the conductive structures;
first upper semiconductor chips disposed on the second redistribution substrate; and
a second molding layer disposed on an upper surface of the second redistribution substrate, and covering the first upper semiconductor chips,
wherein the second redistribution substrate comprises a second insulating layer, a second seed pattern, and a second conductive pattern disposed on the second seed pattern, wherein the second insulating layer comprises a photo sensitive polymer,
wherein the first upper semiconductor chips are apart from the first lower semiconductor chip,
wherein each of the bridge structures comprises:
a base structure; and
conductive vias disposed in the base structure and in contact with the first redistribution substrate, and
wherein the first upper semiconductor chips are electrically connected to the first lower semiconductor chip through the second redistribution substrate and the conductive vias.

18. The semiconductor package of claim 17,
wherein the conductive structures comprise conductive posts,
wherein the first upper semiconductor chips are electrically connected to the conductive posts through the second redistribution substrate,
wherein the conductive vias have a first pitch, and
wherein the conductive posts have a second pitch that is greater than the first pitch.

19. The semiconductor package of claim 17,
wherein the second lower semiconductor chips comprise:
a first edge semiconductor chip spaced apart from a first sidewall of the first lower semiconductor chip at a distance of about 50 μm to about 2 mm;
a second edge semiconductor chip spaced apart from a second sidewall of the first lower semiconductor chip at a distance of about 50 μm to about 2 mm;
a third edge semiconductor chip spaced apart from a third sidewall of the first lower semiconductor chip at a distance of about 50 μm to about 2 mm; and
a fourth edge semiconductor chip spaced apart from a fourth sidewall of the first lower semiconductor chip at a distance of about 50 μm to about 2 mm.

20. The semiconductor package of claim 17,
wherein the first lower semiconductor chip comprises a first communication intellectual property (IP) unit,
wherein each the second lower semiconductor chips comprises a second communication IP unit, and
wherein each of the first upper semiconductor chips comprises a third communication IP unit.
